(19) United States
(12) Patent Application Publication
(10) Pub. No.: US 2018/0301871 A1
(43) Pub. Date: Oct. 18, 2018

(54) NOVEL PATTERNING OF VCSELS FOR DISPLAYS, SENSING, AND IMAGING

(71) Applicant: Vixar, Plymouth, MN (US)

(72) Inventors: Matthew M. Dummer, Minneapolis, MN (US); Klein L. Johnson, Orono, MN (US); Mary K. Brenner, Plymouth, MN (US)

(73) Assignee: Vixar, Plymouth, MN (US)

(21) Appl. No.: 15/946,290

(22) Filed: Apr. 5, 2018

Related U.S. Application Data
(60) Provisional application No. 62/481,980, filed on Apr. 5, 2017.

(51) Int. Cl. H01S 5/183; H01S 5/026; H01S 5/42; H01S 5/042; H01S 5/022

(52) U.S. Cl. CPC H01S 5/18388; H01S 5/0267; H01S 5/18394; H01S 5/0425; H01S 5/02288; H01S 5/423

(57) ABSTRACT

The present disclosure relates to novel and advantageous VCSELs and VCSEL arrays. In particular, the present disclosure relates to novel and advantageous VCSELs and VCSEL arrays having, or patterned in, unique shapes, including rectangular shapes, linear shapes, shapes having two or more segments, and other non-circular shapes. Additionally, VCSELs and VCSEL arrays of the present disclosure may be combined with optical elements. In some embodiments, optical elements may be monolithically integrated on the VCSEL dies, or may be monolithically integrated on standoff pedestals arranged on the VCSEL dies.

### CROSS-REFERENCE TO RELATED APPLICATIONS

The present disclosure claims priority to Provisional Application No. 62/481,980, entitled Novel Patterning of VCSELs for Displays, Sensing, and Imaging, and filed Apr. 5, 2017, the content of which is hereby incorporated by reference herein in its entirety.

### FIELD OF THE INVENTION

The present disclosure relates to vertical-cavity surface-emitting lasers (VCSELs) and VCSEL arrays. Particularly, the present disclosure relates to VCSEL dies patterned with unique shapes.

### BACKGROUND OF THE INVENTION

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

VCSELs and VCSEL arrays are important technology for applications within a variety of markets, including but not limited to, the consumer, industrial, automotive, and medical industries. Example applications include, but are not limited to, illumination for security cameras, illumination for sensors such as three-dimensional (3D) cameras or gesture recognition systems, medical imaging systems, light therapy systems, or medical sensing systems such as those requiring deep penetration into tissue. In such optical sensing and illumination applications as well as other applications, VCSELs and VCSEL arrays offer several benefits, as will be described in further detail herein, including but not limited to, power efficiency, narrow spectral width, narrow beam divergence, and significant packaging flexibility.

Indeed, for VCSELs and VCSEL arrays, power conversion efficiency (PCE) of greater than 30% can be achieved at wavelengths in the 660-1000 nm range. PCE may be defined as the ratio of optical power emitted from a laser(s), such as a VCSEL or VCSEL array, divided by the electrical power used to drive the laser(s). While VCSEL PCE, alone, is fairly comparable to that for some of the most efficient light-emitting diodes (LEDs) currently available, when spectral width and beam divergence are considered, there are significant efficiency benefits to VCSELs over LEDs.

For example, VCSEL arrays generally have a spectral width of approximately 1 nm. This allows the use of filters for a photodetector or camera in order to reduce the noise associated with background radiation. For comparison, an LED typically has a spectral linewidth of 20-50 nm, resulting in the rejection of much of the light by such a filter, and hence reducing the effective PCE of the LED. In addition, the wavelength of a VCSEL is less sensitive to temperature, increasing only around 0.06 nm per 1° Celsius increase in temperature. The VCSEL rate of wavelength shift with temperature is four times less than in a LED.

Also, for example, the angular beam divergence of a VCSEL is typically 10-30 degrees full width half maximum (FWHM), whereas the output beam of a LED is Lambertian, filling the full hemisphere. This means that generally all, if not all, of the light of a VCSEL can be collected using various optical elements, such as lenses for a collimated or focused beam profile, diffusers for a wide beam (40-90 degrees or more) profile, or a diffractive optical element to generate a pattern of spots or lines. Due to the wide beam angle of a LED, it can be difficult to collect all or nearly all of the light (leading to further degradation of the effective PCE), and also difficult to direct the light as precisely as is possible with a VCSEL

The vertically emitting nature of a VCSEL also gives it much more packaging flexibility than a conventional laser, and opens up the door to the use of the wide range of packages available for LEDs or semiconductor integrated circuits (ICs). In addition to integrating multiple VCSELs on the same chip, as will be described in further detail below, one can package VCSELs or VCSEL arrays with photodetectors or optical elements. Plastic or ceramic surface mount packaging or chip-on-board options are also available to the VCSEL.

VCSEL geometry traditionally limits the amount of optical power an individual VCSEL can provide. To illustrate the issue, FIG. 1 is a diagram of the cross-section of a typical VCSEL 100, and includes general structural elements and components that may be utilized, as an example, for VCSEL and VCSEL array embodiments disclosed herein. In general, epitaxial layers of a VCSEL may typically be formed on a substrate material 102, such as a GaAs substrate. On the substrate 102, single crystal quarter wavelength thick semiconductor layers may be grown to form mirrors (e.g., n- and p-distributed Bragg reflectors (DBRs)) around a quantum well based active region to create a laser cavity in the vertical direction. For example, on the substrate 102, first mirror layers 104 may be grown, such as but not limited to layers forming an AlGaAs n-DBR, where the n- designates n-type doping. A spacer 106, such as but not limited to an AlGaInP spacer for wavelengths below 720 nm, or AlGaAs for wavelengths above 720 nm, may be formed over the first mirror layers 104. Then a quantum well based active region 108, such as but not limited to an AlGaInP/GaInP multiple quantum well (MQW) active region for wavelengths less than 720 nm may be formed, along with another spacer layer 110, such as but not limited to an AlGaInP spacer. Over that, second mirror layers 112 may be grown, such as but not limited to layers forming an AlGaAs p-DBR, where the p- designates p-type doping, over which a current spreader/cap layer 114 may be formed, such as but not limited to, an AlGaAs/GaAs current spreader/cap layer. For wavelengths above 720 nm, the spacer layer 110 may be AlGaAs or GaAs. Active regions can consist of AlGaAs/AlGaAs for wavelengths from 720 nm up to 820 nm, or AlGaAs/GaAs for wavelengths from 800 nm to 870 nm, or AlGaAs/InGaAs for wavelengths above 870 nm. A contacting metal layer 116 may be formed over the cap layer 114, leaving an aperture 118, typically with a round shape, of desired diameter generally centered over the axis of the VCSEL. In some embodiments, a dielectric cap 120 may be formed within the aperture 118. As will be explained in more detail below with specific reference to certain embodiments of the present disclosure, a mesa 122, typically with a round shape, may be formed by etching down through the epitaxial structure of the VCSEL to expose a higher aluminum containing layer or layers 124 for oxidation. The oxidation process leaves an electrically conductive approximately round aperture 126 in the oxidized layer or layers that is generally aligned with the aperture 118 defined by the contacting metal layer 116, providing confinement of current to the middle of the VCSEL 100.

More specific details regarding VCSEL structure and fabrication as well as additional VCSEL embodiments and methods for making and using VCSELs are disclosed, for example, in: U.S. Pat. No. 8,249,121, titled “Push-Pull Modulated Coupled Vertical-Cavity Surface-Emitting Lasers and Method;” U.S. Pat. No. 8,494,018, titled “Direct Modulated Modified Vertical-Cavity Surface-Emitting Lasers and Method;” U.S. Pat. No. 8,660,161, titled “Push-Pull Modulated Coupled Vertical-Cavity Surface-Emitting Lasers and Method;” U.S. Pat. No. 8,989,230, titled “Method and Apparatus Including Movable-Mirror MEMS-Tuned Surface-Emitting Lasers;” U.S. Pat. No. 9,088,134, titled “Method and Apparatus Including Improved Vertical-Cavity Surface-Emitting Lasers;” U.S. Reissue Pat. No. RE41,738, titled “Red Light Laser;” U.S. Publ. No. 2015/0380901, titled “Method and Apparatus Including Improved Vertical-Cavity Surface-Emitting Lasers;” U.S. Publ. No. 2016/0352074, titled “VCSELs and VCSEL Arrays Designed for Improved Performance as Illumination Sources and Sensors,” and International Publ. No. WO 2017/218467, titled “Improved Self-Mix Module Utilizing Filters,” of which the contents of each are hereby incorporated by reference herein in their entirety. Without being limited to solely the VCSELs described in any one of the foregoing patents or patent applications, VCSELs suitable for various embodiments of the present disclosure or suitably modifiable according to the present disclosure include the VCSELs disclosed in the foregoing patents or patent applications, including any discussion of prior art VCSELs therein, as well as VCSELs disclosed in any of the prior art references cited during examination of any of the foregoing patents or patent applications. More generally, unless specifically or expressly described otherwise, any VCSEL now known or later developed may be suitable for various embodiments of the present disclosure or suitably modifiable according to the present disclosure.

For efficient operation of a VCSEL, a method for providing current confinement in the lateral direction (achieved with the electrically insulating oxidation layer shown) to force current flow through the center of the device is often required. The metal contact on the surface of the device may provide a means for injecting current into the VCSEL. As described above, the metal contact should have an opening or aperture in order to allow the light to leave the VCSEL. There is a limit to how far current can be spread efficiently across this aperture, and hence there is a limit to the lateral extent of the laser, and in turn, the maximum power that can be emitted from a single round aperture. One solution to this, for applications requiring more power, is to create an array of VCSELs on a chip. In such an approach, the total output power can be scaled simply by scaling the number of VCSEL devices or apertures. These VCSELs are typically arranged in a square, rectangular, or hexagonal grid, although other, less regular arrangements can be used. FIG. 2 illustrates an example layout for a VCSEL die or chip 200 with, for example, one hundred eleven (111) VCSEL devices/apertures 202. A common metal layer 204 on the top surface of the chip 200 (or similar contact mechanism) may contact the anode of each VCSEL device 202 simultaneously, and a common cathode contact (or similar contact mechanism) may be made on the backside of the chip, allowing all the VCSEL devices to be driven in parallel.

An array approach not only solves the technical issue of emitting more optical power, but also provides important advantages. For example, a conventional single coherent laser source results in speckle, which adds noise. However, speckle contrast can be reduced through the use of an array of lasers which are mutually incoherent with each other.

Another advantage or benefit is that of improved eye safety. An extended source is generally more eye safe than a point source emitting the same amount of power. Still another advantage or benefit is the ability to better manage thermal heat dissipation by spreading the emission area over a larger substrate area.

Requirements for an optical source typically depend upon the application and the sensing mechanism used. For example, illumination for night vision cameras may involve simply turning on the light source to form constant uniform illumination over a wide angle which is reflected back to the camera. However, additional illumination schemes can provide more information, including but not limited to, three-dimensional (3D) information. FIGS. 3A-C illustrate example sensing mechanisms—structured lighting, time-of-flight, and modulated phase shift—used to gather information in three dimensions. As illustrated in FIG. 3A, in structured lighting, a pattern (e.g., dots, lines, more complex patterns, etc.) 302 may be imposed upon the light source 304, and then one or more cameras 306 are used to detect distortion in the structure of the light to estimate distance. As conceptually illustrated in FIG. 3B, in a time-of-flight approach, a time-gated camera may be used to measure the roundtrip flight time of a light pulse. As graphically illustrated in FIG. 3C, in the case of modulated phase shift, an amplitude modulation may be imposed upon the emitted light, and the phase shift between the emitted beam and reflected beam may be recorded and used to estimate the distance traveled.

Typically, requirements of an optical light source for any given application may include consideration of one or more of the following:

1. Optical output power: Sufficient power is required for illumination of the area of interest. This can range from tens of milliwatts optical power, such as for a sensing range of a generally a few centimeters, to hundreds of milliwatts, such as for games or sensing of generally a meter or two or so, to ten watts, such as for collision avoidance systems, and kilowatts of total power, such as for a self-driving car.

2. Power efficiency: Particularly for mobile consumer devices, a high efficiency in converting electrical to optical power is desirable and advantageous.

3. Wavelength: For many applications, including most consumer, security, and automotive applications, it may be preferable that the illumination be unobtrusive to the human eye, and often in the infrared region. On the other hand, low cost silicon photodetectors or cameras limit the wavelength on the long end of the spectrum. For such applications, a desirable range therefore, may be generally around or between 800-900 nm. However, some industrial applications may prefer a visible source for the purpose of aligning a sensor, and some medical applications may rely on absorption spectra of tissue, or materials with sensitivity in the visible regime, primarily around 650-700 nm.

4. Spectral width and stability: The presence of background radiation, such as sunlight, can degrade the signal-to-noise ratio of a sensor or camera. This can be compensated with a spectral filter on the detector or camera, but implementing this without a loss of efficiency often requires a light source with a narrow and stable spectrum.

5. Modulation rate or pulse width: For sensors based, for example, upon time of flight or a modulation phase shift, the achievable pulse width or modulation rate of the optical source can determine the spatial resolution in the third dimension.

6. Beam divergence: A wide variety of beam divergences might be specified, depending upon whether the sensor is targeting a particular spot or direction, or a relatively larger area.

7. Packaging: The package provides the electrical and optical interface to the optical source. It may incorporate an optical element that helps to control the beam profile, and may generate a structured lighting pattern. Particularly for mobile devices or other small devices, the overall packaging would desirably be as compact as possible. Surface mount packages, compatible with standard board assembly techniques are almost always preferred over through hole packages such as TO headers.

There are also some applications where a linear source or pattern is desired. This might favor a conventional edge emitting laser, or an array of edge-emitting lasers due to their asymmetric beam shape, having a wider angle in one direction than the other. However, the packaging of such a laser is difficult to achieve in a surface mount package. It also lacks some of the advantages of a VCSEL, which include a more stable spectrum, and a 4× slower shift in wavelength with temperature.

In view of the foregoing, there is a need in the art for VCSELs or arrays of VCSELs having unique shapes, including but not limited to linear shapes. Particularly, there is a need in the art for VCSELs or arrays of VCSELs having unique shapes while providing improved efficiency in converting electrical power to optical power, reduced beam divergence, and relatively compact packaging.

### BRIEF SUMMARY OF THE INVENTION

The following presents a simplified summary of one or more embodiments of the present disclosure in order to provide a basic understanding of such embodiments. This summary is not an extensive overview of all contemplated embodiments, and is intended to neither identify key or critical elements of all embodiments, nor delineate the scope of any or all embodiments.

The present disclosure, in one or more embodiments, relates to a vertical cavity surface emitting laser (VCSEL) device having two sides defining a length and two sides defining a width, wherein the VCSEL has an aspect ratio of at least 12.5. In some embodiments, the aspect ratio may be at least 25, or at least 250. In some embodiments, the length of the VCSEL may be at least 0.2 mm or at least 1 mm. The VCSEL may have four substantially rounded corners, each having a radius of curvature of approximately half the width of the VCSEL. In some embodiments, the radius of curvature of each corner may be at least 1.5 μm. In some embodiments, the VCSEL may have a cylindrical lens. In some embodiments, the cylindrical lens may be monolithically integrated on the VCSEL. In other embodiments, the cylindrical lens may be monolithically integrated on a standoff pedestal arranged between the lens and the VCSEL.

The present disclosure, in one or more embodiments, additionally relates to an array of VCSELs fabricated on a single chip, each VCSEL having two sides defining a length and two sides defining a width, wherein the VCSEL has an aspect ratio of at least 12.5. In some embodiments, the VCSELs of the array may share a common cathode and a common anode. In other embodiments, the VCSELs may share a common cathode, and two or more VCSELs may be connected to a separate anode contact, allowing them to be independently modulated. In some embodiments, each VCSEL may have its own cathode and anode contact, with the anode cathode contact formed by etching from a top surface down to an n-side of the VCSEL diode and making a metal contact to a bottom surface of the etch. In some embodiments, the VCSELs may be segmented into groups, with each group having a common cathode contact. Moreover, the VCSEL array may have an array of cylindrical lenses having one lens per VCSEL, to focus the light emitted from the VCSELs.

The present disclosure, in one or more embodiments, additionally relates to a patterned VCSEL having a non-circular shape comprising at least two segments. Each segment may have a dimension of not more than 25 μm in some embodiments. Moreover, each VCSEL may have at least one rounded corner with a radius of curvature of at least 1.5 μm.

The present disclosure, in one or more embodiments, additionally relates to an array of patterned VCSELs, wherein at least one VCSEL of the array has a non-circular shape comprising at least two segments. In some embodiments, the VCSEL shapes may be varied across the array in shape, size, and/or orientation. In some embodiments, the array may include a macroscopic collimating lens to project the pattern to form a display. In other embodiments, the array may have an optical element, such as a lens, diffractive optical element, and/or a grating.

While multiple embodiments are disclosed, still other embodiments of the present disclosure will become apparent to those skilled in the art from the following detailed description, which shows and describes illustrative embodiments of the invention. As will be realized, the various embodiments of the present disclosure are capable of modifications in various obvious aspects, all without departing from the spirit and scope of the present disclosure. Accordingly, the drawings and detailed description are to be regarded as illustrative in nature and not restrictive.

### BRIEF DESCRIPTION OF THE DRAWINGS

While the specification concludes with claims particularly pointing out and distinctly claiming the subject matter that is regarded as forming the various embodiments of the present disclosure, it is believed that the invention will be better understood from the following description taken in conjunction with the accompanying Figures, in which:

FIG. 1 is a schematic diagram of the cross-section of a conventional VCSEL.

FIG. 2 is an example of a schematic layout for a VCSEL array chip with, for example, 111 VCSEL apertures.

FIG. 3A is a diagram illustrating a structured lighting sensing mechanism.

FIG. 3B is a diagram illustrating a time-of-flight sensing mechanism.

FIG. 3C is a diagram illustrating a modulated phase shift sensing mechanism.

FIG. 4 is a schematic diagram of an array of linear VCSELs divided into two segments of 4 rectangular VCSELs each, according to one or more embodiments.

FIG. 5 is a schematic diagram of an array of linear VCSELs divided into two segments of 4 rectangular VCSELs each, according to other embodiments.

FIG. 6A is a schematic diagram of an array of VCSEL stripes, with each stripe having its own bond pad for independent control of each stripe, according to one or more embodiments.

FIG. 6B is an image of an array of VCSEL stripes, with each stripe having its own bond pad for independent control of each stripe, according to one or more embodiments.

FIG. 7A is an image of an array of round VCSELs.

FIG. 7B is an image of a linear stripe VCSEL, according to one or more embodiments.

FIG. 8 is a plot showing optical output power and voltage versus current for an array of round VCSELs and an array of stripe VCSELs, indicating the threshold behavior seen in lasers.

FIG. 9 shows plots of the far field beam shape of a stripe VCSEL in the direction parallel to the short side of the stripe (top) and parallel to the long side of the stripe (bottom), according to one or more embodiments.

FIG. 10A is a schematic diagram of a rectangular VCSEL with sharp corners, according to one or more embodiments.

FIG. 10B is a plot of output power and voltage versus current for the VCSEL shown in FIG. 10A, according to one or more embodiments.

FIG. 11A is a schematic diagram of an alternative layout of a stripe VCSEL with rounded corners, according to one or more embodiments.

FIG. 11B is a plot of output power and voltage versus current for the VCSEL shown in FIG. 11A, according to one or more embodiments.

FIG. 12 is a schematic diagram of a wider stripe VCSEL where the corners are rounded, but the short side of the stripe also includes a linear segment, according to one or more embodiments.

FIG. 13 is a plot of power conversion efficiency versus stripe width for four stripe VCSEL arrays of the present disclosure having different lengths and VCSEL densities.

FIG. 14A is a schematic diagram of a patterned VCSEL with multiple VCSEL rectangular segments simulating an 8-segment LED display, according to one or more embodiments.

FIG. 14B is a schematic diagram of a patterned VCSEL consisting of round and rectangular shapes, according to one or more embodiments.

FIG. 15A is a plot showing the far field beam shape (intensity versus angle) for a multi-mode round VCSEL aperture.

FIG. 15B is a plot showing the far field beam shape (intensity versus angle) for the short direction of a stripe VCSEL, according to one or more embodiments.

FIG. 15C is a plot showing the far field shape (intensity versus angle) for a patterned VCSEL, according to one or more embodiments.

FIG. 16A is a schematic diagram of a VCSEL patterned to spell out the word “Vixar,” according to one or more embodiments.

FIG. 16B is an image of an activated patterned VCSEL spelling out the word “Vixar,” according to one or more embodiments.

FIG. 17 is a schematic example of a VCSEL die layout that includes a variety of VCSEL shapes and orientations, according to one or more embodiments.

FIG. 18 is an image illustrating how lenses could be formed directly on a VCSEL die, according to one or more embodiments.

FIG. 19 is an image illustrating the formation of lenses on standoff pedestals directly on a VCSEL die, according to one or more embodiments.

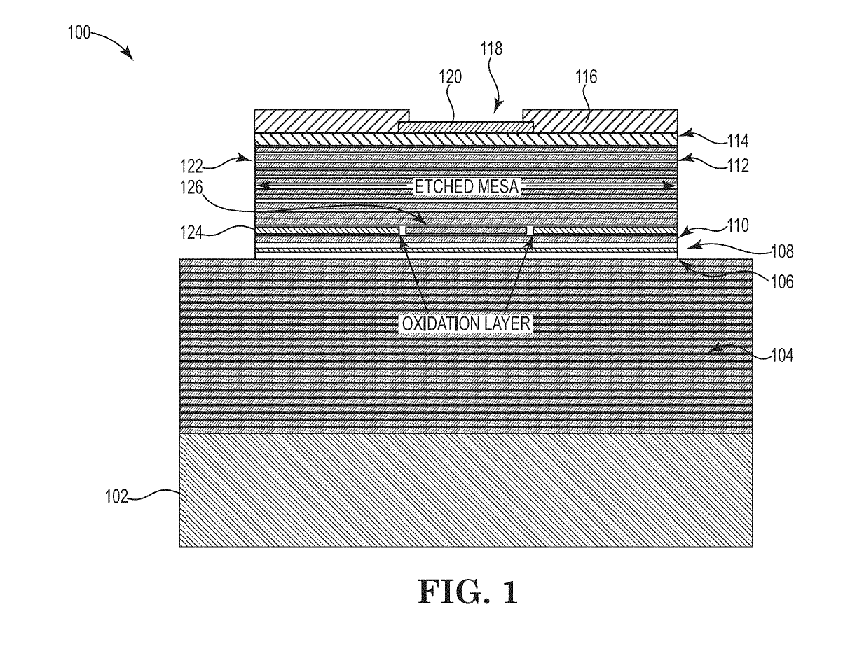

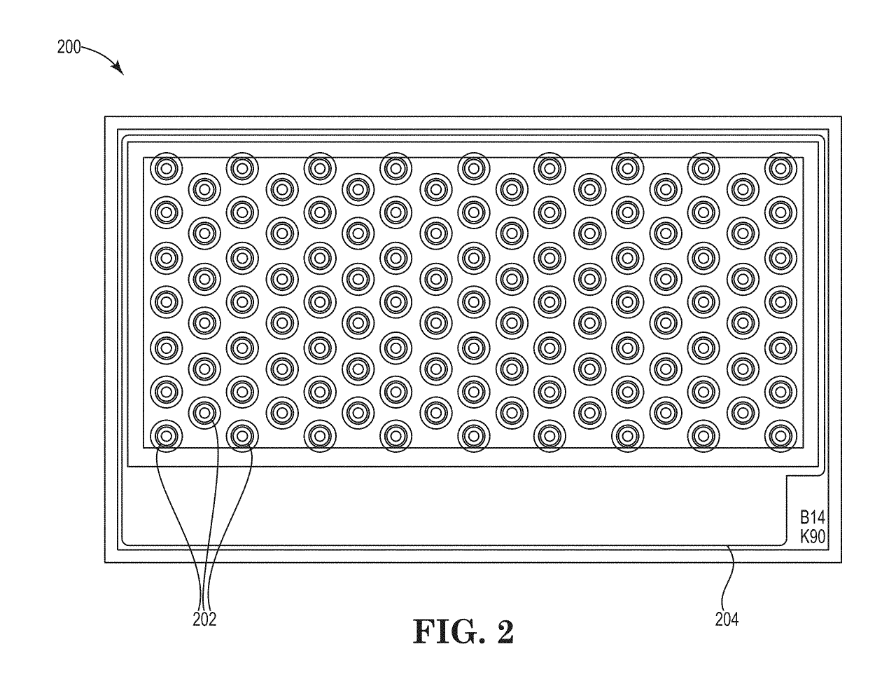

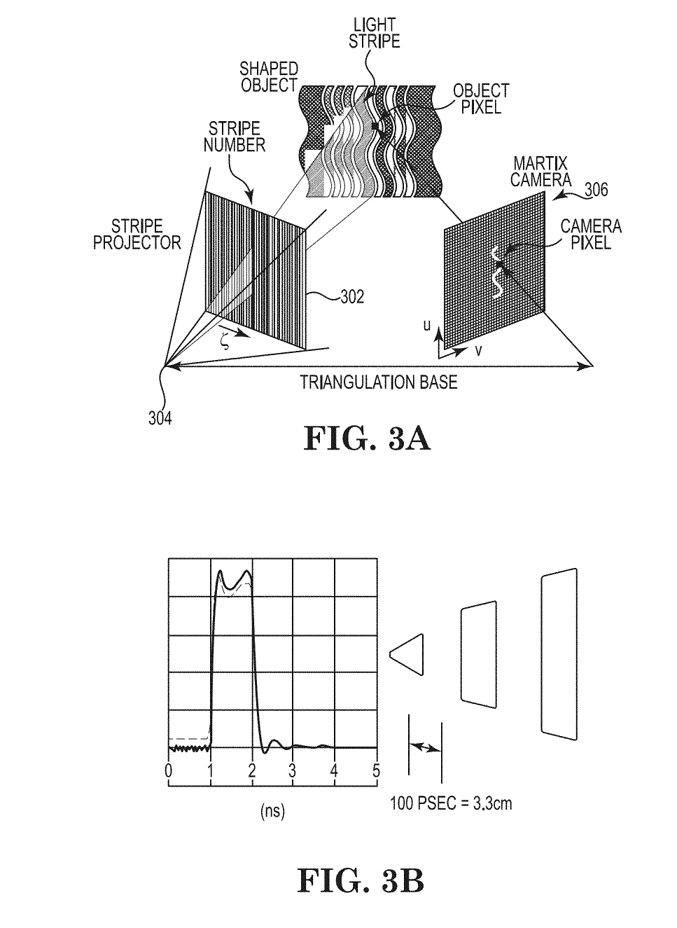

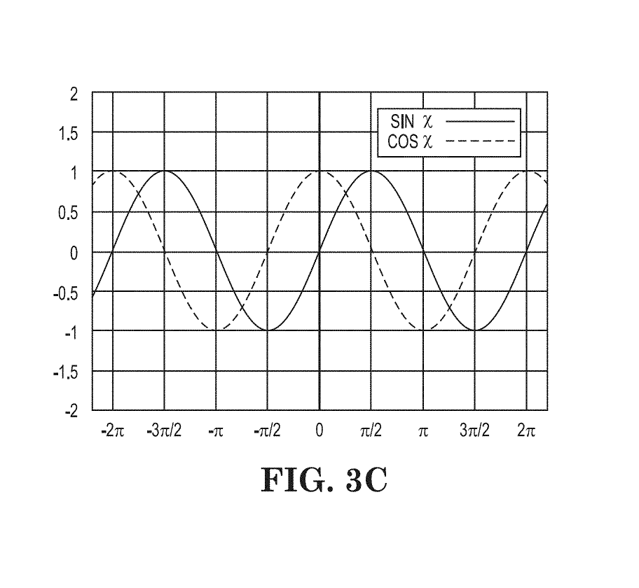

### DETAILED DESCRIPTION

The present disclosure relates to novel and advantageous VCSELs and VCSEL arrays. In particular, the present disclosure relates to novel and advantageous VCSELs and VCSEL arrays having, or patterned in, unique shapes, including rectangular shapes, linear shapes, shapes having two or more segments, and other non-circular shapes. Additionally, VCSELs and VCSEL arrays of the present disclosure may be combined with optical elements. In some embodiments, optical elements may be monolithically integrated on the VCSEL dies, or may be monolithically integrated on standoff pedestals arranged on the VCSEL dies.

In some embodiments, a VCSEL of the present disclosure may have a generally rectangular shape or linear shape. That is, a VCSEL may have an aperture shape with two parallel sides of a first length and two parallel sides of a second length, wherein the first length is shorter than the second length. Additionally, such a VCSEL may have four corners defined by the four sides. Such aperture shapes may be referred to herein as rectangular, linear, or as stripe VCSELs. Some simple extensions of the VCSEL have been reported, such as single rectangular VCSELs designed to achieve higher power, such as in Gronenborn, et al. (Applied Physics B (2011) 105:783-792), the contents of which are hereby incorporated by reference herein in their entirety. For the same emitting area, the rectangular VCSEL was found to provide improved efficiency and low voltage as compared to the same size round VCSEL.

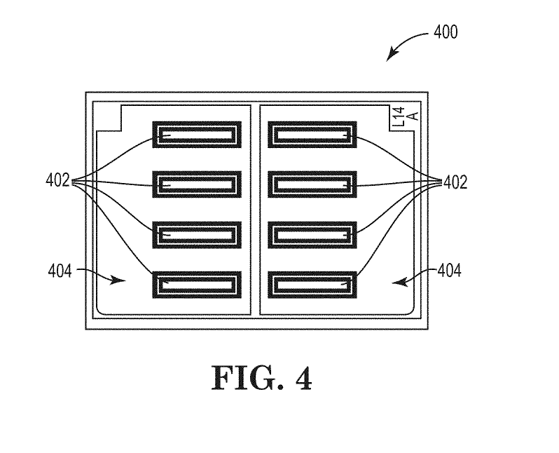

FIG. 4 illustrates one embodiment of a VCSEL die 400 with a plurality of rectangular VCSEL apertures 402. Each aperture 402 may have a length (i.e. a long side length) of approximately 175 μm in some embodiments. In other embodiments, each aperture may have a longer or shorter length. In some embodiments, a VCSEL aperture 402 may have a length of more than 0.1 mm or more than 0.2 mm. The VCSEL apertures 402 may have a width (i.e. a short side length) of approximately 14 μm in some embodiments. In other embodiments, each aperture 402 may have a wider or narrower width. In some embodiments, a VCSEL or VCSEL aperture of the present disclosure may have an aspect ratio of at least or greater than 12.5, at least or greater than 25, or at least or greater than 250. The VCSEL die 400 may be configured with any suitable number of rectangular or linear VCSEL apertures 402. For example, as shown in FIG. 4, the die 400 may have eight apertures 402. In some embodiments, apertures may be grouped with a shared cathode metal 404 connecting each group. For example, as shown in FIG. 4, eight apertures 402 may be grouped into two groups of 4, each group having a cathode metal 404. In other embodiments, the die 400 may have different groupings or arrangements.

A VCSEL having a rectangular or linear shape, such as those shown in FIG. 4, may be fabricated by etching a rectangular mesa, rather than a more conventional round mesa. A current confinement region may be formed by converting a high aluminum content AlGaAs layer into aluminum oxide, by placing the wafer in a steam atmosphere. The distance of the oxidation front from the edge, which determines the opening in the oxide which allows current flow, may be based upon the time the wafer is in the oxidizing atmosphere. Generally, the oxidation front may be designed to be approximately co-incident with the top metal aperture, which may be deposited later in the process. The metal aperture may be sized with dimensions within +/−2 μm of the size of the oxide aperture in some embodiments, although it can be even larger or smaller in other embodiments.

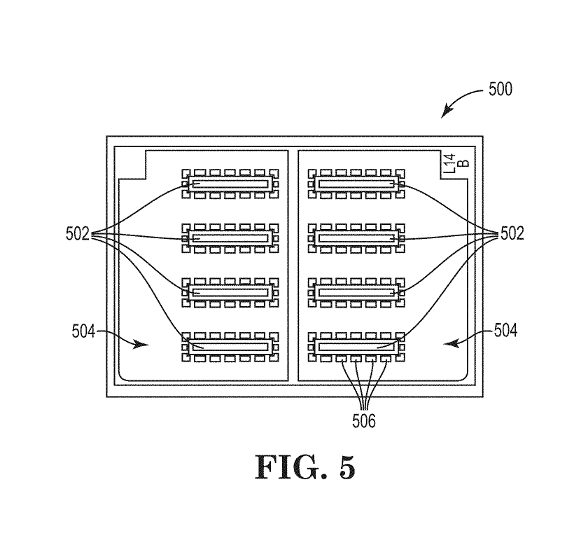

FIG. 5 illustrates another VCSEL die 500 with a plurality of rectangular or linear VCSEL apertures 502 arranged on metal contact areas 504. FIG. 5 illustrates an alternative way of fabricating the rectangular VCSEL shape. In this case, instead of etching a mesa all the way around the intended VCSEL area, one may etch multiple trenches 506 into the VCSEL epitaxial structure that extend deeper than the oxidation layer. In some embodiments, these trenches are not connected to each other. However, when the structure is placed into an oxidizing atmosphere, the oxidation may proceed outward from each trench in all directions. The oxidation fronts of the trenches may eventually meet up to form a continuous oxide layer that surrounds the intended VCSEL aperture area. This approach can provide some additional thermal advantages to the structure.

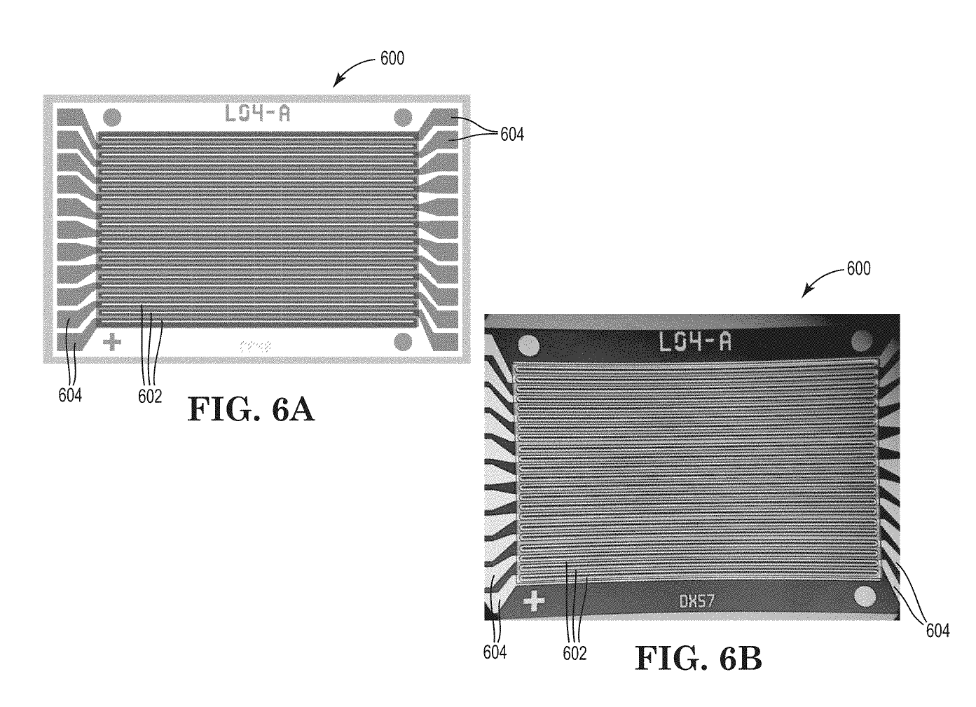

FIGS. 6A and 6B illustrate schematic diagram and an image, respectively, of a VCSEL die 600 with an array of linear VCSELs 602. Each VCSEL 602 may have any suitable length and width. In some embodiments, the VCSELs 602 may each have a length of approximately 1.3 mm and a width of approximately 4 μm. However, in other embodiments, the VCSELs 602 may have longer or shorter lengths, and wider or narrower widths. In some embodiments, each VCSEL 602 may be connected to a probe pad 604 on the die 600, such that each VCSEL 602 may be driven independently of the others. Alternatively, in other embodiments, two or more VCSELs 602 may be grouped or segmented with a metal layer surrounding or connecting each group or segment, such that an electrical contact to the metal may power the VCSELs of a group or segment simultaneously. In some embodiments, all of the VCSELs may be driven together using a same metal layer and electrical contact.

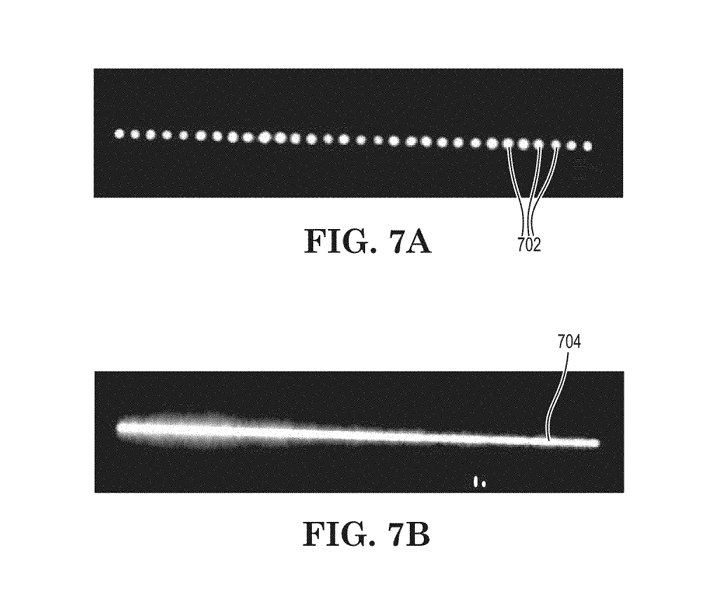

A rectangular, linear, or stripe VCSEL may provide advantages over a plurality of conventionally shaped round VCSELs arranged in a line. FIG. 7A shows a row of such conventional round VCSELs 702 in a linear pattern, while FIG. 7B shows a linear or stripe VCSEL 704 of similar length to the row of round VCSELs. To create a line of light with conventional round VCSELs, an optical element may be generally required to spread the light in a linear direction. In contrast, a stripe VCSEL may provide a simpler and more effective means of producing a line of light. Moreover, when a plurality of round VCSELS is arranged in a line, as shown in FIG. 7A, there may be spacing around each emitting aperture determined largely by the fabrication process. One may need to leave space for the mesa etch for accessing the layer to be oxidized, as well as the oxidation distance. In contrast, for a linear VCSEL, such as that shown in FIG. 7B, a solid line of light may be provided. Thus with respect to a linear VCSEL, a higher density of the active area of the VCSEL may be provided. This has an advantage in that the area of chip required to achieve a particular output power can be reduced, by creating an array of long, relatively thin lines as illustrated for example in FIGS. 4, 5, and 6.

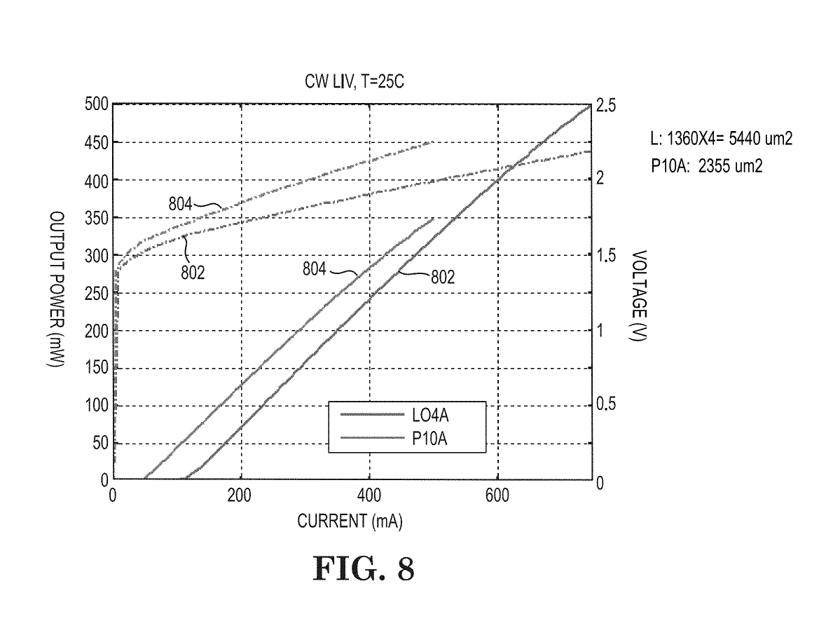

Additionally, a rectangular, linear, or stripe VCSEL of the present disclosure may provide other advantages associated with laser light, such as improved efficiency in converting electrical power to optical power, in reduced beam divergence, and in a relatively narrow spectrum. FIG. 8 illustrates a graph of optical output power versus input current and voltage versus input current for both a stripe VCSEL 802 and a line of conventional round VCSELs 804. The stripe VCSEL 802 represented in this graph has a length of approximately 1.3 mm and a width of approximately 4 μm. The line of conventional round VCSELs 804 represented in the graph has a length of approximately 1.3 mm and a width of approximately 50 μm. The active area of the stripe VCSEL may be approximately twice that of the line of circular VCSELs. As shown in FIG. 8, both devices have a threshold current where the device begins to lase, and the output power increases dramatically as current increases. The threshold current for the line of round VCSELs 804, as shown in the graph of FIG. 8, may be approximately 60 mA, while the threshold current for the linear VCSEL 802 may be approximately 120 mA This is consistent with the linear VCSEL covering approximately twice the area of the line of round VCSELs. One can also see that the resistance of the stripe VCSEL is much lower than that of the row of round VCSELs, which may be primarily due to the larger emitting area. While the magnitudes of the power and voltage differ, the comparison clearly shows that the stripe VCSEL is lasing in a similar manner to the line of circular VCSELs, and that a higher density of lasing area can be achieved in the same total space with the stripe VCSEL.

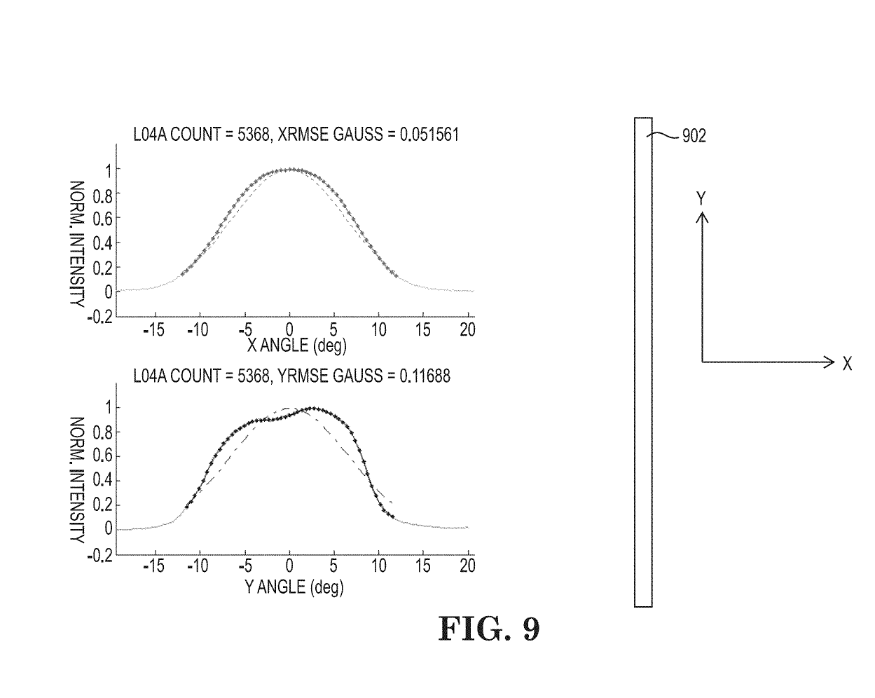

FIG. 9 illustrates beam divergence characteristics for a stripe VCSEL, according to some embodiments. FIG. 9 shows a stripe VCSEL 902 oriented with respect to X and Y axes. As shown, in this particular example, the width of the stripe VCSEL 902 (or the shorter dimension) is aligned with the x-axis, and the length of the VCSEL (or the longer dimension) is aligned with the y-axis. Two graphs illustrate the intensity versus angle of the VCSEL 902 parallel to the x-direction and parallel to the y-direction, in accordance with the orientation shown. In this example, the VCSEL 902 has a width of approximately 4 μm and a length of approximately 1.3 mm. However, a stripe VCSEL may have any other suitable dimensions. As shown in the two graphs, the beam is relatively narrow (<20 degrees full width half maximum) in both directions, which suggests that the emitted light is the stimulated emission of a laser. A difference in beam shape is also shown between the x-direction and y-direction. The beam measured in the x-direction is Gaussian or nearly Gaussian, while the beam in the y-direction is wider and has two lobes, which may indicate multi-mode behavior. The dimension of the linear device in the x-direction is small enough to limit the emission to a single mode, while the long dimension in the y-direction would support multiple modes.

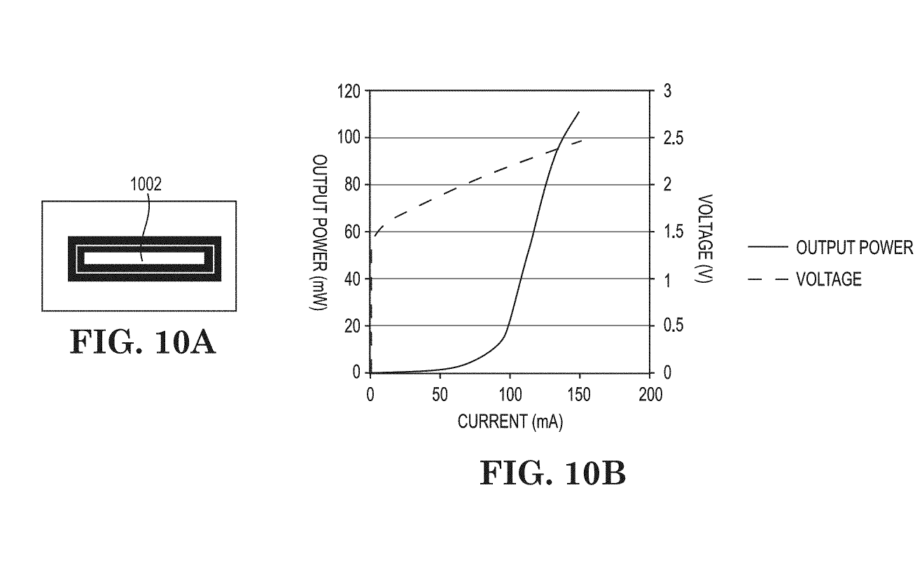

In some embodiments, a rectangular, linear, or stripe VCSEL of the present disclosure may have 90-degree or substantially 90-degree internal corners. As shown for example in the VCSEL 1002 of FIG. 10A, the two short sides and two long sides of the rectangular shape may form four corners, each having an internal angle. Each of the four internal angles of the rectangular shape may have a 90-degree or approximately 90-degree angle. In some embodiments, a rectangular VCSEL having squared or 90-degree corners may produce a soft turn-on effect and may exhibit earlier turn on of the corners, indicating a higher current density in the corners. FIG. 10B shows a plot of output power and voltage as a function of current through the VCSEL 1002 of FIG. 10A. One can see the soft turn-on of power versus current at threshold, in this example between approximately 50 mA and approximately 100 mA.

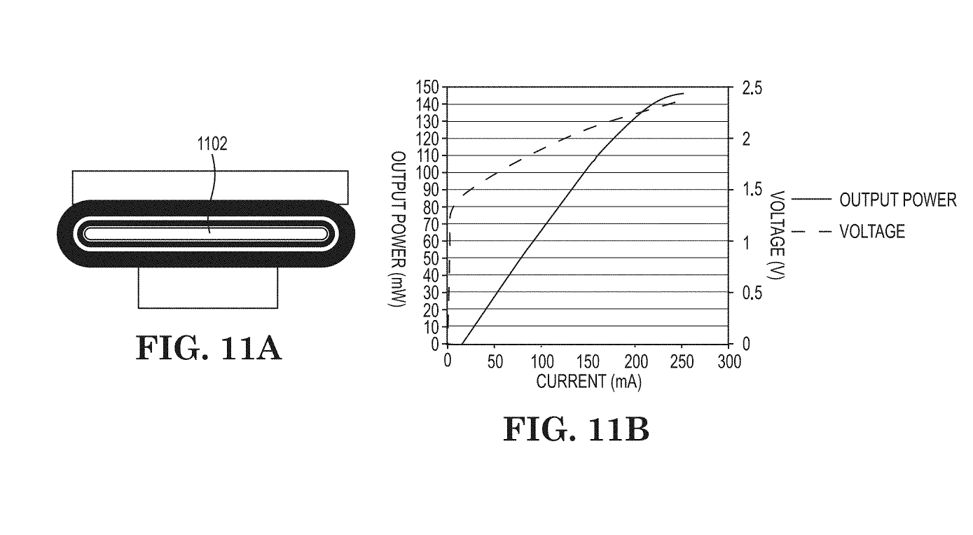

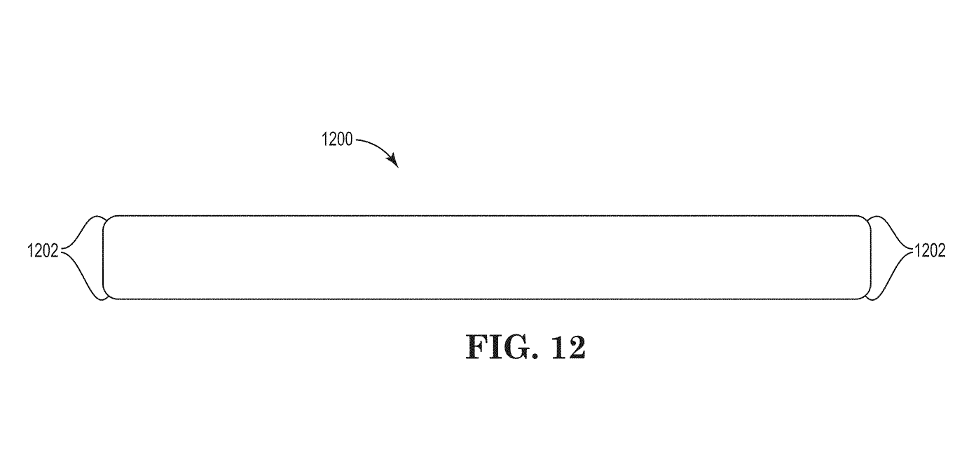

In other embodiments, a rectangular, linear, or stripe VCSEL of the present disclosure may have one or more internal corners having a finite radius of curvature. For example, FIG. 11 shows a rectangular VCSEL 1102 with four internal angles formed by the two short sides and two long sides of the rectangular shape. In one embodiment, each of the four internal angles of the rectangular shape may have a radius of curvature of approximately one half of the width of the VCSEL. For example, where the VCSEL has a width of approximately 4 μm and a length of more than 4 μm, the radius of curvature of each internal angle may be approximately 2 μm. As another example, where the VCSEL has a width of approximately 14 μm, the radius of curvature of each internal angle may be approximately 7 μm. However, in other embodiments, different corners of a VCSEL may have different radii of curvature. For example, FIG. 12 illustrates another rectangular VCSEL 1200 having rounded corners to help achieve relatively reliable operation and relatively uniform turn-on of the VCSEL. The VCSEL 1200 may have a generally rectangular shape formed by two parallel sides of a first length and two parallel sides of a second length shorter than the first length. Each corner 1202 of the VCSEL may have a generally rounded shape with a radius of curvature. The four corners 1202 may all have the same radius of curvature, or may have different radii of curvature. In some embodiments, one or more corners 1202 may have a radius of curvature of approximately 1.5 microns, or more than 1.5 microns. In other embodiments, one or more corners 1202 may have a radius of curvature of less than 1.5 microns. FIG. 11B shows a plot of output power and voltage as a function of current through the VCSEL 1102 of FIG. 11A. As shown, the VCSEL 1102 may have a sharp turn-on of power at the threshold current of approximately 20 mA.

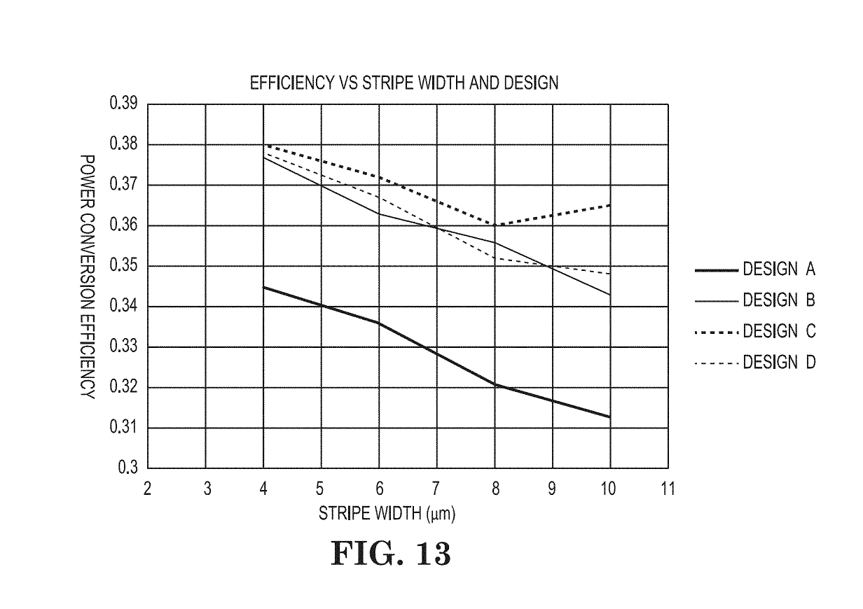

In some embodiments, the width of a linear, rectangular, stripe VCSEL, or a segment width for a VCSEL having a different shape, may be determined based, at least in part, on a desired efficiency and/or output power. In general, the efficiency of a VCSEL array may be a function of epitaxial design, mask layout, density of emitting area, and/or other factors. As such, the width of a linear VCSEL may be an important feature. FIG. 13 shows a plot of power conversion efficiency of some linear VCSEL array dies as a function of the width of the VCSELs in the short direction. Four different designs are included in the plot, labelled A, B, C, and D. Each of the four designs has VCSELs of different lengths (in the long direction) and different VCSEL densities. However, all four designs show the same trend, i.e. that the VCSEL becomes more efficient as the width narrows. It is to be appreciated, however, that this parameter can be traded off with other goals such as total power emitted from the chip. In some embodiments, the width of a linear VCSEL, or of a segment of a differently shaped VCSEL, may be less than 25 μm. In some embodiments, a VCSEL width of less than 12 μm may be preferred. However, in other embodiments, a linear VCSEL or a segment of a differently shaped VCSEL may have a width of less than 12 μm, less than 10 μm, or less than 6 μm.

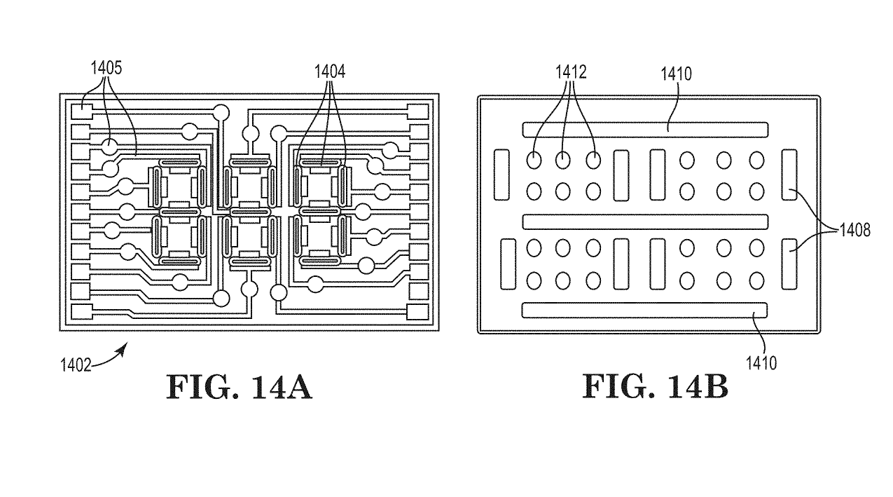

Linear, rectangular, or stripe VCSELs may be arranged in generally any pattern. As shown and described with respect to FIGS. 4, 5, and 6, an array may have a plurality of linear VCSELs arranged in parallel lines. Additionally or alternatively, in some embodiments, linear, rectangular, or stripe VCSELs may be arranged in other designs or patterns. For example, FIG. 14A illustrates a VCSEL array 1402 having linear VCSELs 1404 arranged in figure-eight patterns. As a particular example, seven linear VCSELs 1404 may be arranged in a figure-eight shape, and 21 VCSELs may provide three figure-eight shapes. Each VCSEL 1404 may have its own bond pad 1405, such that each segment may be individually driven. The individually addressable segments of each figure-eight shape may be used to display, for example, a numeral between 0-9. Linear, rectangular, or stripe VCSELs may be arranged in other suitable patterns to achieve a desired display and/or desired illumination pattern are envisioned as well. FIG. 14B illustrates an embodiment of an array 1406 having linear VCSELs 1408 of a first length, linear VCSELs 1410 of a second length arranged perpendicular to the VCSELs 1408 of the first length, and circular VCSELs 1412 arranged together in a desired pattern. Other arrays may include linear and/or circular VCSELs of varying sizes arranged in any suitable pattern or configuration.

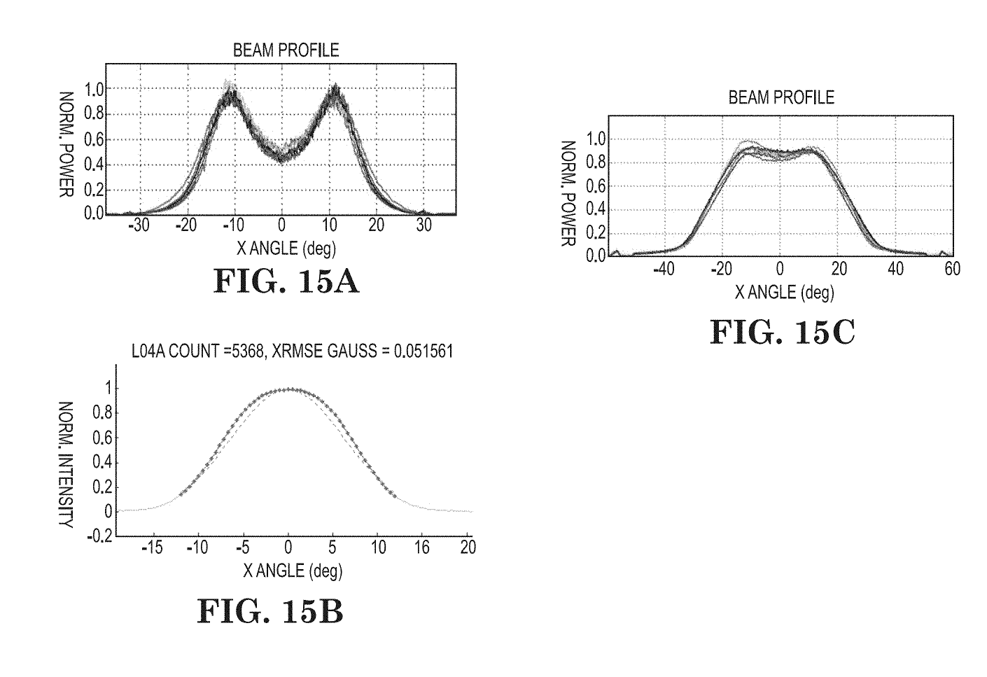

In some embodiments, die layouts combining linear and circular VCSELs, such as the example array 1406 shown in FIG. 14B, may provide improved control over the beam profile. For instance, FIG. 15A illustrates the beam profile of a relatively large, round and multi-mode VCSEL. This plots the beam intensity versus beam angle, with 0 degrees being the direction perpendicular to the plane of the VCSEL die. For the multi-mode device, the pattern tends to be radially symmetric, with a somewhat lower intensity in the 0 degree direction, and a peak of intensity of some angle around 10 degrees from normal. FIG. 15B illustrates the beam divergence, previously shown in FIG. 9, of the beam divergence measured in the short direction across a linear VCSEL, when the short direction was approximately 4 μm. FIG. 15C suggests a combined beam divergence that might result from the combined linear and circular VCSEL design of FIG. 14B, which may look like a beam with a relatively or near constant intensity versus angle out to a particular angle, and then may drop off to close to zero at relatively high angles. This is sometimes referred to as a “flat top” beam. This may result from the circular VCSELs contributing a donut shape, while the linear VCSELs arranged in perpendicular directions, or in a different arrangement, may provide a Gaussian shape that may generally fill in the intensity in the 0 degree direction. The pattern may be designed to create this, or other, beam divergence patterns.

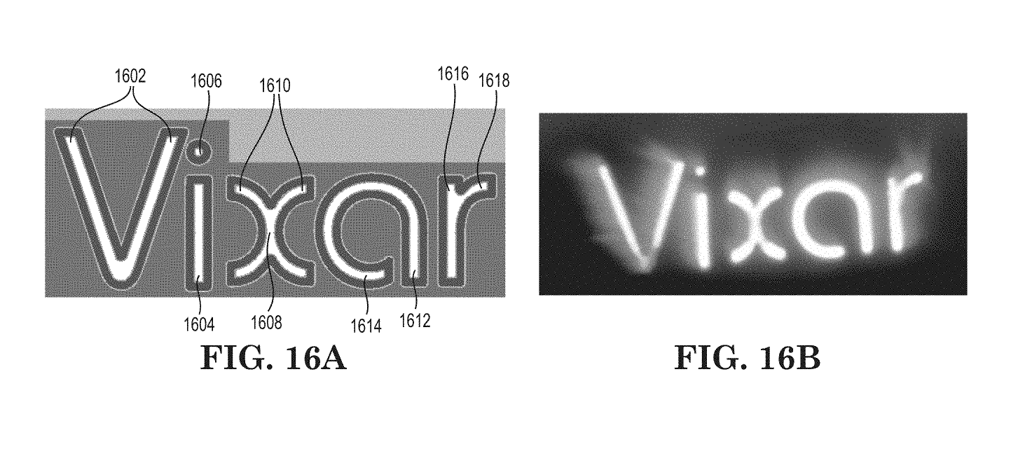

In addition to rectangular, linear, or stripe VCSELs, in some embodiments, VCSELs of the present disclosure may have other non-circular shapes. For example, a VCSEL may be configured to have any suitable number of sides and corners, and one or more arcs, angles, or bends. In some embodiments, a VCSEL of the present disclosure may have two or more segments, which may be joined together at one or more corners, angles, or bends. FIG. 16A shows one embodiment a pattern of VCSELs, wherein each VCSEL is provided in the shape of a letter, to spell the word VIXAR. For example, a VCSEL having two segments 1602 joined at an angle may form the letter “V.” A rectangular VCSEL 1604 and a round VCSEL 1606 may be arranged adjacent to one another to form the letter “i.” A VCSEL having a central linear segment 1608, and two arced segments 1610 extending from each end of the central segment, may form the letter “X.” A VCSEL having a linear portion 1612 and an arced portion 1614 may form the letter “a,” and a VCSEL having a rectangular segment 1616 and an arced segment 1618 extending therefrom may form the letter “r.” FIG. 16B shows an image of a projection produced by a chip with the VCSEL arrangement of FIG. 16A. It is to be appreciated that any desired shape may be formed by VCSEL segments with linear or curved VCSELs having different lengths, radii of curvature, or other properties.

A VCSEL having a non-circular shape with one or more segments, such as those shown in FIG. 16A, may be fabricated by etching a suitably shaped mesa, rather than a more conventional round mesa. A current confinement region may be formed by converting a high aluminum content AlGaAs layer into aluminum oxide, by placing the wafer in a steam atmosphere. As described above with respect to rectangular VCSELs, the distance of the oxidation front from the edge, which determines the opening in the oxide which allows current flow, may be based upon the time the wafer is in the oxidizing atmosphere. Moreover, in some embodiments, a non-circular VCSEL may be formed by etching multiple trenches into the VCSEL epitaxial structure that extend deeper than the oxidation layer, as shown and described for example with respect to FIG. 5. The oxidation fronts of the trenches may eventually meet up to form a continuous oxide layer that surrounds the intended VCSEL aperture area with the desired non-circular shape. In some embodiments, one or more segments of a patterned or non-circular VCSEL may have at least one dimension (such as a length or width) of 25 μm or less.

Some traditional illumination sources combine a light source with a slide projector or a transparency with, for example, a fixed pattern of spots. For example, U.S. Pat. No. 7,164,789 by Chen et al. describes the use of what they refer to as a “glyph carpet” projected onto a three-dimensional object, and then recording the image of the projected glyph carpet onto an image detecting device. In this patent, the inventors anticipate using a slide projector to generate the “glyph carpet” pattern, i.e. an optical source illuminates a separate slide, or using a digital projector (meaning a projector consisting of an array of micromirrors that are manipulated to reflect light to create a pattern). In the case of a slide projector, the projection is energy inefficient, in that the slide is uniformly illuminated, but only some of the light is allowed through, and the rest is wasted. In the case of the use of a digital projector, a relatively expensive device (the micro-mirror array) is required in addition to the light source to create the pattern. Patent publication WO 2008120217 A2 also describes the use of an illumination assembly, comprising: a single transparency containing a fixed pattern of spots; and a light source, which is configured to transilluminate the single transparency with optical radiation so as to project the pattern onto the object; an image capture assembly, which is configured to capture an image of the pattern that is projected onto the object using the single transparency; and a processor, which is coupled to process the image captured by the image capture assembly so as to reconstruct a three-dimensional (3D) map of the object.

In contrast to such traditional illumination sources, with the patterning of light proposed in the present disclosure, the light source and the pattern on the transparency can be effectively combined into the same semiconductor chip. Current may be consumed by the areas designed to emit the light pattern, but generally not consumed or thrown away by the dark areas, in contrast to a light source combined with a slide. In comparison with the conventional slide projector and transparency methods described above, advantages of VCSEL approaches of the present disclosure include, but are not limited to: a) improved efficiency by generating light only in the pattern desired, b) the elimination of extra components such as a slide or a digital micromirror array, c) a more compact illumination source due to the elimination of extra components, and d) lower cost due to the smaller size and illumination of extra components.

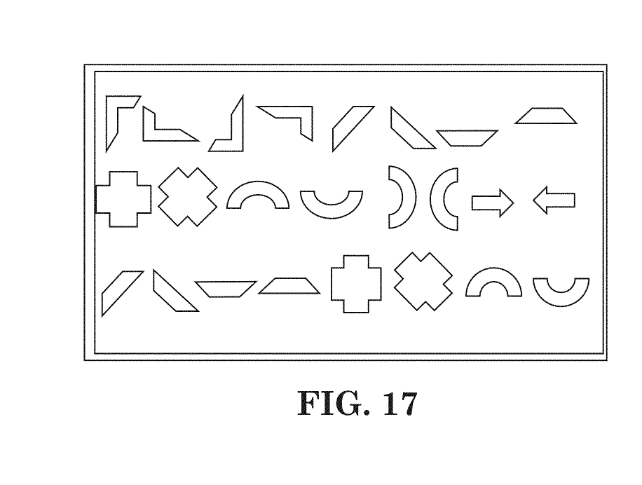

A VCSEL array can be used for 3D imaging by designing an array of spots on the VCSEL chip that have a particular spacing or density. US Publication No. 2016/0025993 describes methods of 3D imaging or 3D mapping by overlapping projections of a pattern of spots from an array of round VCSELs. In contrast to round VCSELs, rectangular and other non-circular VCSEL shapes of the present disclosure may be used to project unique patterns to collect information for 3D mapping. In this way, a VCSEL die of the present disclosure having non-circular VCSELs could be used to project uniquely shaped spots for mapping a 3D object or scene. For example, FIG. 17 of the present disclosure illustrates a patterned arrangement of a VCSEL die with several different shapes in multiple orientations incorporated into a single VCSEL die. Such a patterning of various VCSEL shapes and orientations may be used to provide a much richer set of information about the 3D object or scene than is provided by the patterning of round spots. In some embodiments, an array of VCSELs may have any suitable combination of shapes, sizes or orientations. In some embodiments, a same shape or series of shapes may be repeated across the die with a regular or pseudo random pattern. In some embodiments, such an array may be combined with an optical element, such as a macroscopic collimating lens or other lens to project the pattern to the far field to form a display.

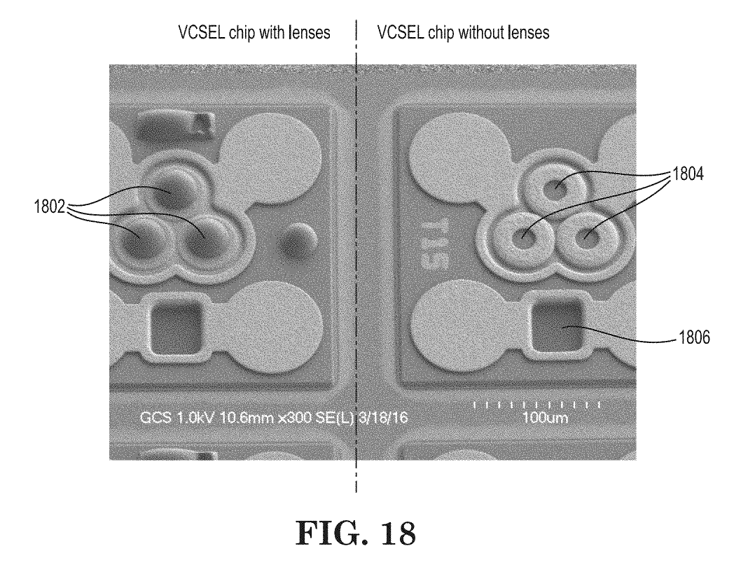

A VCSEL or VCSEL array of the present disclosure may be combined with an optical element, such as a lens, diffractive optical element (DOE), grating, or other element. For example, in some embodiments, a lens may be integrated directly on a VCSEL die to reduce or expand the beam divergence of the VCSEL. In some embodiments, the lens may be monolithically integrated on the VCSEL. FIG. 18 illustrates one example of how such lenses 1802 may be integrated with round VCSELs 1804. However, such lenses may have the same or similar partial collimation or expansion effect on VCSELs that are not round. The lenses 1802 may be fabricated by depositing and patterning a polymer material on the VCSEL die. After patterning circles of polymer material, a re-flow process may be used to form the lens shape. In some embodiments, a reflowed photoresist may be used to transfer a curbed lens shape. The images in FIG. 18 also illustrate one example of how a device with co-planar contacts may be fabricated, such as by etching a deep trench 1806 to the n-doped side of the diode and making a metal contact to the bottom of the trench.

While shown in FIG. 18 with respect to round VCSELs, such cylindrical lenses may also be formed by the same or similar processes with respect to stripe VCSELs or VCSELs of other shapes. For example, a line may be patterned in the polymer material that overlaps the stripe aperture of a linear VCSEL. A reflow process, such as those described above, may be used to transform the polymer material into a cylindrical lens.

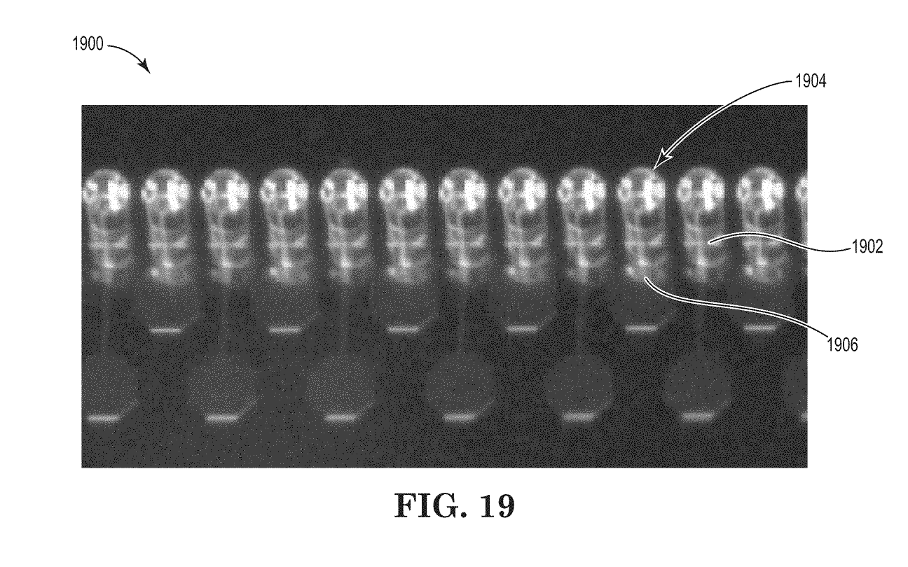

In some embodiments, where a lens is deposited directly on the VCSEL die, the closeness of the lens to light emitting layers of the VCSEL may limit its effectiveness as a collimating or focusing lens, and may reduce the beam divergence of the VCSEL. However, according to some embodiments, a lens may be fabricated by providing a spacer on the chip. One approach that can be used, for example, for devices emitting at wavelengths longer than about 900 nm is to create a bottom emitting VCSEL and place lenses on the substrate side of the wafer. This may be used at longer wavelengths in some embodiments. Alternatively, a spacer may be built on the top surface of the wafer. FIG. 19 illustrates an example of such a spacer according to one embodiment. In some embodiments, a photoresist having a thickness of approximately 50-100 μm, or any other suitable thickness, may be formed on a VCSEL die 1900 having VCSEL apertures 1906, and patterned to form a pedestal 1902. In some embodiments, a polymer material may be ink jet printed on top of the pedestal 1902 and the surface tension may cause it to form a lens shape 1904. This process may create a lens which can provide improved collimation. Other means for forming the lens on the wafer or on the pedestal on the wafer can be used in other embodiments.

While shown in FIG. 19 with respect to round VCSELs, such cylindrical lenses and pedestals may also be formed by the same or similar processes with respect to stripe VCSELs or VCSELs of other shapes. For example, in some embodiments, a transparent dielectric material may be deposited on a VCSEL surface and etched in a pattern that follows the shape of the VCSEL shape. In some embodiments, a standoff pedestal may be created by patterning a polymer material by etching, and a lens may be created by depositing a second, lower melting temperature dielectric material over the pedestal and reflowing to form a cylindrical lens. In still other embodiments, other methods may be used to form a standoff pedestal and/or lens.

In some embodiments, a patterned laser source of the present disclosure may be combined with a lens to collimate or focus the light. The patterned laser source could also be combined with a diffractive optical element (DOE) that could project the pattern into multiple repetitions to fill a larger field of view, or by interleaving the replications of the array to create a more dense array. One could also envision a segmented VCSEL chip with multiple patterns on the chip, or multiple VCSEL chips with different patterns on each chip mounted on the same submount or in the same package. The different patterns may be turned on independently, in some embodiments, such as to fill a larger field of view, or to change the pattern in time, by sequentially activating the different segments or chips, for example. The segments could additionally or alternatively be combined with a lens, grating, or DOE to direct the VCSEL pattern of each segment to a different part of a field of view, such as to fill a larger field of view, or to reduce energy consumption by only illuminating the currently interesting part of the field of view, for example.

As used herein, the terms “substantially” or “generally” refer to the complete or nearly complete extent or degree of an action, characteristic, property, state, structure, item, or result. For example, an object that is “substantially” or “generally” enclosed would mean that the object is either completely enclosed or nearly completely enclosed. The exact allowable degree of deviation from absolute completeness may in some cases depend on the specific context. However, generally speaking, the nearness of completion will be so as to have generally the same overall result as if absolute and total completion were obtained. The use of “substantially” or “generally” is equally applicable when used in a negative connotation to refer to the complete or near complete lack of an action, characteristic, property, state, structure, item, or result. For example, an element, combination, embodiment, or composition that is “substantially free of” or “generally free of” an element may still actually contain such element as long as there is generally no significant effect thereof.

In the foregoing description various embodiments of the present disclosure have been presented for the purpose of illustration and description. They are not intended to be exhaustive or to limit the invention to the precise form disclosed. Obvious modifications or variations are possible in light of the above teachings. The various embodiments were chosen and described to provide the best illustration of the principals of the disclosure and their practical application, and to enable one of ordinary skill in the art to utilize the various embodiments with various modifications as are suited to the particular use contemplated. All such modifications and variations are within the scope of the present disclosure as determined by the appended claims when interpreted in accordance with the breadth they are fairly, legally, and equitably entitled.

What is claimed is:

1. A vertical cavity surface emitting laser (VCSEL) device having two sides defining a length and two sides defining a width, wherein the VCSEL has an aspect ratio of at least 12.5.

2. The VCSEL of claim 1, wherein the aspect ratio is at least 25.

3. The VCSEL of claim 2, wherein the aspect ratio is at least 250.

4. The VCSEL of claim 1, wherein the length is at least 0.2 mm.

5. The VCSEL of claim 5, wherein the length is at least 1 mm.

6. The VCSEL of claim 1, wherein the VCSEL comprises four substantially rounded corners each having a radius of curvature of approximately half the width of the VCSEL.

7. The VCSEL of claim 6, wherein each corner has a radius of curvature of at least 1.5 μm.

8. The VCSEL of claim 1, further comprising a cylindrical lens.

9. The VCSEL of claim 8, wherein the cylindrical lens is monolithically integrated on the VCSEL.

10. The VCSEL of claim 8, wherein the cylindrical lens is monolithically integrated on a standoff pedestal arranged between the lens and the VCSEL.

11. An array of vertical cavity surface emitting lasers (VCSELs) fabricated on a single chip, each VCSEL having two sides defining a length and two sides defining a width, wherein the VCSEL has an aspect ratio of at least 12.5.

12. The array of claim 11, wherein the VCSELs share a common anode and a common cathode.

13. The array of claim 11, wherein the VCSELs share a common cathode, and wherein at least two VCSELs are connected to separate anode contacts, allowing the at least two VCSELs to be independently modulated.

14. The array of claim 11, wherein each VCSEL has its own cathode and anode contact, with the anode cathode contact formed by etching from a top surface down to an n-side of the VCSEL diode and making a metal contact to a bottom surface of the etch.

15. The array of claim 11, wherein the VCSELs are segmented into groups, each group having a common cathode contact.

16. The array of claim 11, further comprising an array of cylindrical lenses having one lens per VCSEL, to focus the light emitted from the linear VCSELs.

17. A patterned vertical cavity surface emitting laser (VCSEL) having a non-circular shape comprising at least two segments.

18. The patterned VCSEL of claim 17, wherein each segment has a dimension of not more than 25 μm.

19. The patterned VCSEL of claim 17, wherein the shape of the VCSEL has at least one rounded corner with a radius of curvature of at least 1.5 μm.

20. An array of patterned vertical cavity surface emitting lasers (VCSELs), at least one VCSEL having a non-circular shape comprising at least two segments.

21. The array of claim 20, wherein the shapes of a plurality of the VCSELs are varied across the array in at least one of shape, size, and orientation.

22. The array of claim 20, further comprising a macroscopic collimating lens to project the pattern to form a display.

23. The array of claim 20, further comprising an optical element, wherein the optical element comprises at least one of a lens, a diffractive optical element, and a grating.
